(19) United States
(12) Patent Application Publication
(10) Pub. No.: US 2009/0053554 A1
(43) Pub. Date: Feb. 26, 2009

(54) THERMAL BARRIER COATING SYSTEM FOR THERMAL MECHANICAL FATIGUE RESISTANCE

(76) Inventors: Christopher W. Strock, Kennebunk, ME (US); Susan M. Tholen, Kennebunk, ME (US)

Correspondence Address: CARLSON, GASKEY & OLDS/PRATT & WHITNEY, 400 WEST MAPLE ROAD, SUITE 350, BIRMINGHAM, MI, 48009, US

(21) Appl. No.: 11/776,082

(22) Filed: Jul. 11, 2007

(51) Int. Cl. B32B 15/04; B05D 1/02; C23C 16/06

(52) U.S. Cl. 428/651; 427/446; 427/255.28

(57) ABSTRACT

A composite article includes a substrate including a first metallic material having a nominal composition, and a bond coat disposed on the substrate. The bond coat includes a second metallic material having the nominal composition of the first metallic material. A ceramic top coat is disposed on the bond coat.

This invention was made with government support under Contract Number F33615-03-D-2354 awarded by the United States Air Force. The government has certain rights in this invention.

### BACKGROUND OF THE INVENTION

This invention relates to protective thermal barrier coatings and, more particularly, to multi-layered thermal barrier coatings.

Components that are exposed to high temperatures, such as a component within a gas turbine engine, typically include a coating system having multiple layers of protective coatings. For example, components within a gas turbine engine such as turbine blades, turbine vanes, and blade outer air seals typically include the coating system to protect the component from erosion, oxidation, corrosion or the like to thereby enhance durability or maintain efficient operation of the engine. Typically, the coating system includes a MCrAlY bond coat, and a ceramic topcoat on the MCrAlY bond coat. The MCrAlY bond coat reacts with oxygen that diffuses through the ceramic topcoat to form an adherent oxide that protects the component from oxidation and corrosion.

Although effective, conventional coating systems often utilize expensive materials and are prone to forming reaction zones between the MCrAlY bond coat and the component. Elemental constituents from the MCrAlY bond coat diffuse and react with refractory metal constituents from the component to form precipitant phases that may reduce resistance to cracking, such as from thermal mechanical fatigue.

Accordingly, there is a need for an inexpensive coating system having an arrangement of layers that reduces or eliminates detrimental reaction zones. This invention addresses those needs while avoiding the shortcomings and drawbacks of the prior art.

### SUMMARY OF THE INVENTION

An example composite article includes a substrate including a first metallic material having a nominal composition, and a bond coat disposed on the substrate. The bond coat includes a second metallic material having the nominal composition of the first metallic material. A ceramic top coat is disposed on the bond coat.

In a further example, the composite article and the bond coat of the composite article are formed from a nickel alloy having the same nominal composition. In embodiments, the bond coat comprises a thickness between 1 mil and 6 mils, and the ceramic top coat is formed from yttria stabilized zirconia, zirconia, gadolinia, or hafnia.

An example method of enhancing durability of a composite article includes the step of establishing a desired level of a thermal mechanical strength of a substrate including a first metallic material having a nominal composition by forming on the substrate a bond coat comprising a second metallic material having the nominal composition of the first metallic material.

### BRIEF DESCRIPTION OF THE DRAWINGS

The various features and advantages of this invention will become apparent to those skilled in the art from the following detailed description of the currently preferred embodiment. The drawings that accompany the detailed description can be briefly described as follows.

FIG. 1 illustrates an example gas turbine engine.

FIG. 2 illustrates a turbine section of the gas turbine engine.

FIG. 3A illustrates a portion of an example seal member within the turbine section.

FIG. 3B illustrates another example of a seal member.

FIG. 3C illustrates another example of a seal member.

FIG. 3D illustrates another example of a seal member.

### DETAILED DESCRIPTION OF THE PREFERRED EMBODIMENT

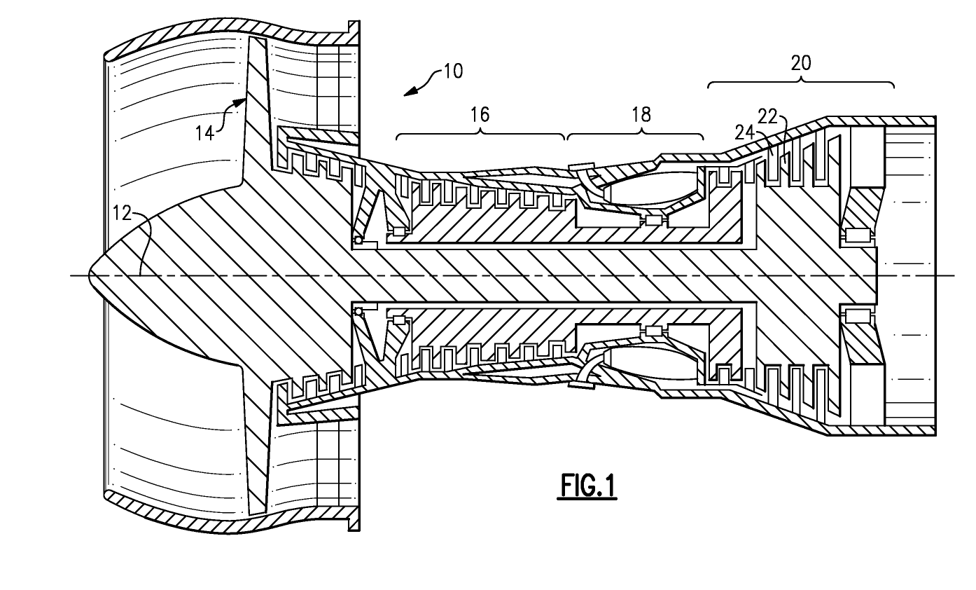

FIG. 1 illustrates selected portions of an example gas turbine engine 10, such as a gas turbine engine 10 used for propulsion. In this example, the gas turbine engine 10 is circumferentially disposed about an engine centerline 12. The engine 10 includes a fan 14, a compressor section 16, a combustion section 18 and a turbine section 20 that includes turbine blades 22 and turbine vanes 24. As is known, air compressed in the compressor section 16 is mixed with fuel that is burned in the combustion section 18 to produce hot gases that are expanded in the turbine section 20. FIG. 1 is a somewhat schematic presentation for illustrative purposes only and is not a limitation on the disclosed examples. Additionally, there are various types of gas turbine engines, many of which could benefit from the examples disclosed herein, which are not limited to the design shown.

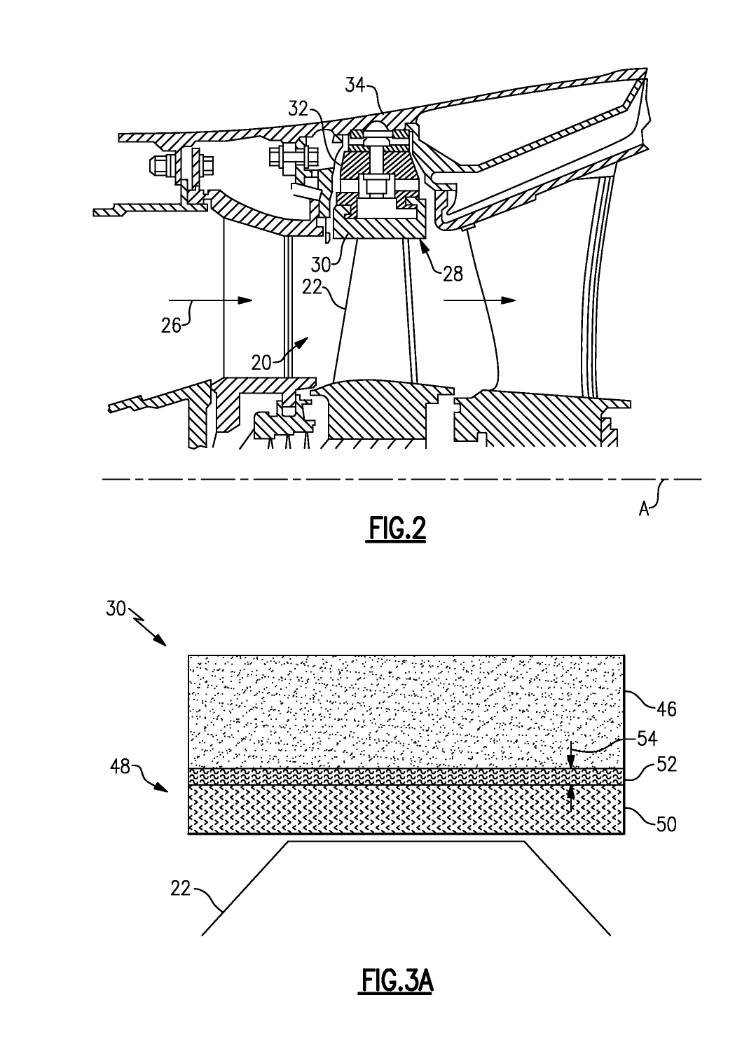

FIG. 2 illustrates selected portions of the turbine section 20. The turbine blade 22 receives a hot gas flow 26 from the combustion section 18 (FIG. 1). The turbine section 20 includes a blade outer air seal system 28 having a seal member 30 that functions as an outer wall for the hot gas flow 26 through the turbine section 20. The seal member 30 is secured to a support 32, which is in turn secured to a case 34 that generally surrounds the turbine section 20. For example, a plurality of the seal members 30 are circumferentially located about the turbine section 20.

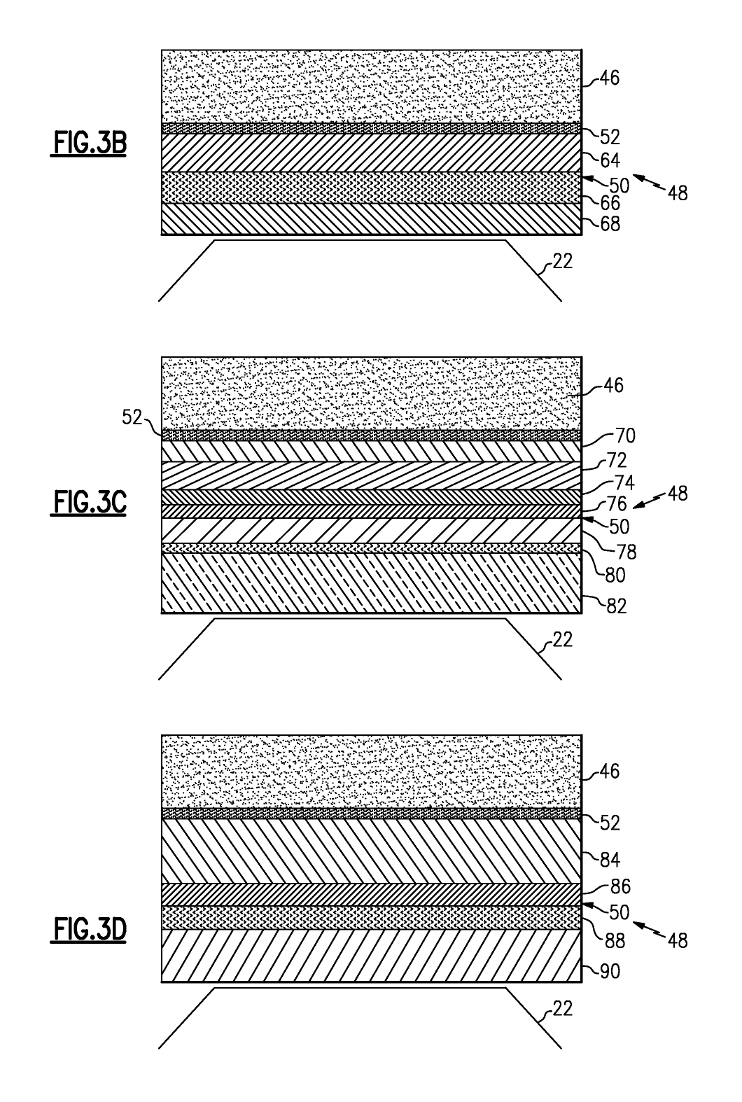

FIG. 3A illustrates an example portion of the seal member 30. In this example, the seal member 30 includes a substrate 46 having a coating system 48 disposed thereon. In this example, the coating system 48 includes a monolayer type of ceramic topcoat 50, such as an abradable ceramic coating, and a bond coat 52 between the ceramic top coat 50 and the substrate 46. Although a particular coating system 48 is shown, it should be understood that the disclosed examples are not limited to the illustrated configuration and may include additional layers. Furthermore, although the disclosed example illustrates the seal member 30, it is to be understood that the examples herein may be applied to other types of engine or non-engine components.

FIG. 3B illustrates another example embodiment of the seal member 30. In this example, the coating system 48 includes a multi-layer type of the ceramic topcoat 50, and the bond coat 52 is between the ceramic top coat 50 and the substrate 46. The ceramic top coat 50 in this example includes a first layer 64, a second layer 66, and a third layer 68. The first layer 64 is graded and includes a composite of cobalt and alumina (Al₂O₃). In one example, the grading is 95/5 to 5/95 of cobalt/alumina, where the “xx/yy” nomenclature represents weight percentages of the given materials. Given this description, one of ordinary skill in the art will recognize that other compositions and gradings may be used to suit their particular needs.

FIG. 3C illustrates another example embodiment of the seal member 30. In this example, the coating system 48 includes another multi-layer type of the ceramic topcoat 50, and the bond coat 52 is between the ceramic top coat 50 and the substrate 46. The ceramic top coat 50 in this example includes layers 70, 72, 74, 76, 78, 80, and 82. For example, layer 70 includes a 60/40 composite of cobalt/alumina. Layer 72 includes a grading of 60/40 to 20/80 of cobalt/alumina. Layer 74 includes a 20/80 composite of cobalt/alumina. Layer 76 includes a grading of 100/0 to 0/100 of alumina/yttria stabilized zirconia (e.g. 20 wt % yttria stabilized zirconia). Layer 78 is 20 wt % yttria stabilized zirconia. Layer 80 includes a grading of 100/0 to 0/100 of 20 wt % yttria stabilized zirconia/7 wt % porous yttria stabilized zirconia. Layer 82 includes 7 wt % porous yttria stabilized zirconia. Given this description, one of ordinary skill in the art will recognize that other compositions and gradings may be used to suit their particular needs.

FIG. 3D illustrates another example embodiment of the seal member 30. In this example, the coating system 48 includes another multi-layer type of the ceramic topcoat 50, and the bond coat 52 is between the ceramic top coat 50 and the substrate 46. The ceramic top coat 50 in this example includes layers 84, 86, 88, and 90. For example, layer 84 includes a grading of 80/20 to 10/90 of cobalt/alumina. Layer 86 includes a grading of 90/10 to 10/90 of alumina/20 wt % yttria stabilized zirconia. Layer 88 includes a grading of 90/10 to 10/90 of 20 wt % yttria stabilized zirconia/7 wt % porous yttria stabilized zirconia. Layer 90 includes 7 wt % porous yttria stabilized zirconia. Given this description, one of ordinary skill in the art will recognize that other compositions and gradings may be used to suit their particular needs.

In the disclosed examples, the bond coat 52 and the substrate 46 are made of materials having the same nominal composition. For example, the substrate 46 is formed from a first nickel alloy material having a first nominal composition, and the bond coat 52 is formed from a second nickel alloy having the nominal composition of the first nickel alloy. In a further example, the substrate 46 and the bond coat 52 each comprise Inconel™ 718 or another type of nickel alloy.

The nominal composition of Inconel™ 718 includes about 50 wt % to 55 wt % of nickel, about 17 wt % to 21 wt % of chromium, about 4.75 wt % to 5.5 wt % of a mix of columbium and tantalum, about 2.8 wt % to 3.3 wt % of molybdenum, about 0.65 wt % to 1.15 wt % of titanium, about 0.2 wt % to 0.8 wt % of aluminum, and a balance of iron. Optionally, the nominal composition of Inconel™ 718 may also include up to about 1 wt % of cobalt, up to about 0.08 wt % of carbon, up to about 0.35 wt % of manganese, up to about 0.35 wt % of silicon, up to about 0.015 wt % of phosphorous, up to about 0.015 wt % of sulphur, up to about 0.006 wt % of boron, up to about 0.3 wt % of copper, or combinations thereof. Additionally, Inconel™ 718 may include impurities that do not affect the properties of the alloy or elements that are unmeasured or undetectable in the alloy.

In another example, the substrate 46 may comprise a nickel alloy that includes about 5.9 wt % of tungsten, about 5 wt % of chromium, about 10 wt % of cobalt, about 5.65 wt % of aluminum, about 8.7 wt % of tantalum, about 1.9 wt % of molybdenum, about 3.0 wt % of rhenium, about 0.10 wt % hafnium, and a balance of nickel. Additionally, the alloy may include impurities that do not affect the properties of the alloy or elements that are unmeasured or undetectable in the alloy.

Using a nominal composition of the bond coat 52 that is the same as the nominal composition of the substrate 46 establishes a desired level of thermal mechanical strength (e.g., thermal mechanical fatigue) of the substrate 46. For example, in prior thermal barrier systems that utilize a bond coat having a different composition from a substrate, elemental constituents within the bond coat interdiffuse with the substrate. Over time, the elemental constituents react with the substrate to reduce the thermal mechanical strength of the substrate (i.e., increasing a rate of reduction in the thermal mechanical strength of the substrate. However, in the disclosed example, because the nominal composition of the bond coat 52 is the same as the nominal composition of the substrate 46, interdiffusion does not occur or is insignificant because the elements are present in the same amounts. Thus, by using the same nominal composition, the detrimental reactions with the substrate 46 are limited or eliminated to thereby maintain the thermal mechanical strength of the substrate 46 (e.g., limiting the rate of reduction in the thermal mechanical strength).

In the disclosed example, the bond coat 52 provides a dual function of establishing a desired level of thermal mechanical strength of the substrate 46 and providing a rough surface for bonding of the ceramic top coat 50. For example, the bond coat 52 is formed on the substrate 46 using a thermal spray process, a vapor deposition process, or the like that results in a surface roughness of the bond coat 52 that is greater than the roughness of the surface of the substrate 46. The ceramic top coat 50 is then formed on the bond coat 52 and mechanically interlocks with the roughness provided by the bond coat 52.

In the disclosed examples, the bond coat 52 is not relied on to provide an oxidative layer, as are conventional bond coats that provide an oxidative protective layer. Conventional bond coats require a minimum thickness to provide the oxidative layer. However, since the disclosed bond coat 52 does not provide an oxidative layer, a more compact thickness may be used. For example, the bond coat 52 comprises a thickness 54 between about 1 mil (0.025 mm) and 12 mils (0.305 mm).

The ceramic top coat 50 includes a ceramic material, such as a ceramic material suitable for functioning as a thermal barrier within the turbine section 20 of the gas turbine engine 10. For example, the ceramic top coat 50 includes yttria stabilized zirconia (e.g., 7 wt % yttria stabilized zirconia), zirconia, gadolinia, hafnia, or combinations thereof. In one example, the zirconia, gadolinia, or hafnia comprises a composition disclosed in U.S. Pat. No. 6,284,323 or U.S. Pat. No. 6,924,040. Given this description, one of ordinary skill in the art will recognize additional ceramic materials to meet their particular needs.

Although a combination of features is shown in the illustrated examples, not all of them need to be combined to realize the benefits of various embodiments of this disclosure. In other words, a system designed according to an embodiment of this disclosure will not necessarily include all of the features shown in any one of the Figures or all of the portions schematically shown in the Figures. Moreover, selected features of one example embodiment may be combined with selected features of other example embodiments.

The preceding description is exemplary rather than limiting in nature. Variations and modifications to the disclosed examples may become apparent to those skilled in the art that do not necessarily depart from the essence of this disclosure. The scope of legal protection given to this disclosure can only be determined by studying the following claims.

What is claimed is:

1. A composite article comprising:
a substrate comprising a first metallic material having a nominal composition;
a bond coat disposed on the substrate, the bond coat comprising a second metallic material having the nominal composition of the first metallic material; and
a ceramic top coat disposed on the bond coat.

2. The composite article as recited in claim 1, wherein the nominal composition comprises nickel.

3. The composite article as recited in claim 1, wherein the nominal composition comprises about 50 wt % to 55 wt % of nickel, about 17 wt % to 21 wt % of chromium, about 4.75 wt % to 5.5 wt % of a combination of columbium and tantalum, about 2.8 wt % to 3.3 wt % of molybdenum, about 0.65 wt % to 1.15 wt % of titanium, about 0.28 wt % to 0.8 wt % of aluminum, and a balance of iron.

4. The composite article as recited in claim 3, wherein the nominal composition additionally includes at least one of up to about 1 wt % of cobalt, up to about 0.08 wt % of carbon, up to about 0.35 wt % of manganese, up to about 0.35 wt % of silicon, up to about 0.015 wt % of phosphorous, up to about 0.015 wt % of sulphur, up to about 0.006 wt % of boron, up to about 0.3 wt % of copper, and combinations thereof.

5. The composite article as recited in claim 1, wherein the nominal composition comprises about 5.9 wt % of tungsten, about 5 wt % of chromium, about 10 wt % of cobalt, about 5.65 wt % of aluminum, about 8.7 wt % of tantalum, about 1.9 wt % of molybdenum, about 3.0 wt % of rhenium, about 0.10 wt % hafnium, and a balance of nickel.

6. The composite article as recited in claim 1, wherein the bond coat comprises a thickness of about 1 mil to 12 mils.

7. The composite article as recited in claim 1, wherein the ceramic top coat comprises at least one of: yttria stabilized zirconia, zirconia, gadolinia, hafnia.

8. The composite article as recited in claim 1, wherein the ceramic top coat comprises multiple layers.

9. The composite article as recited in claim 1, wherein the ceramic top coat comprises at least one graded layer.

10. The composite article as recited in claim 1, wherein the substrate, the bond coat, and the ceramic top coat together comprise a turbine blade outer air seal.

11. The composite article as recited in claim 1, wherein the substrate comprises a first surface roughness and the bond coat comprises a second surface roughness that is greater than the first surface roughness.

12. The composite article as recited in claim 1, wherein the substrate, the bond coat, and the ceramic top coat together comprise an engine component.

13. A method of enhancing durability of a composite article, comprising:
(a) establishing a desired level of thermal mechanical strength of a substrate comprising a first metallic material having a nominal composition by forming on the substrate a bond coat comprising a second metallic material having the nominal composition of the first metallic material.

14. The method as recited in claim 13, wherein said step (a) further includes at least one of thermal spraying or vapor depositing the bond coat onto the substrate.

15. The method as recited in claim 13, further comprising limiting diffusion induced reduction of the thermal mechanical strength of the substrate by using the nominal composition for each of the substrate and the bond coat.

16. The method as recited in claim 13, further comprising establishing a desired surface roughness of the bond coat that is greater than a surface roughness of the substrate.

17. A composite article comprising:
a substrate comprising a first nickel alloy having a nominal composition;
a bond coat having a thickness of about 1 mil to 12 mils disposed on the substrate, the bond coat comprising a second nickel alloy having the nominal composition of the first nickel alloy; and
a ceramic top coat disposed on the bond coat, the ceramic topcoat including at least one of yttria stabilized zirconia, zirconia, gadolinia, or hafnia.

18. The composite article as recited in claim 17, wherein the nominal composition comprises about 50 wt % to 55 wt % of nickel, about 17 wt % to 21 wt % of chromium, about 4.75 wt % to 5.5 wt % of a combination of columbium and tantalum, about 2.8 wt % to 3.3 wt % of molybdenum, about 0.65 wt % to 1.15 wt % of titanium, about 0.28 wt % to 0.8 wt % of aluminum, and a balance of iron.

19. The composite article as recited in claim 18, wherein the nominal composition additionally includes at least one of up to about 1 wt % of cobalt, up to about 0.08 wt % of carbon, up to about 0.35 wt % of manganese, up to about 0.35 wt % of silicon, up to about 0.015 wt % of phosphorous, up to about 0.015 wt % of sulphur, up to about 0.006 wt % of boron, up to about 0.3 wt % of copper, and combinations thereof.

20. The composite article as recited in claim 17, wherein the nominal composition comprises about 5.9 wt % of tungsten, about 5 wt % of chromium, about 10 wt % of cobalt, about 5.65 wt % of aluminum, about 8.7 wt % of tantalum, about 1.9 wt % of molybdenum, about 3.0 wt % of rhenium, about 0.10 wt % hafnium, and a balance of nickel.

21. The composite article as recited in claim 17, wherein the substrate, the bond coat, and the ceramic top coat together comprise a turbine blade outer air seal.

22. The composite article as recited in claim 17, wherein the substrate comprises a first surface roughness and the bond coat comprises a second surface roughness that is greater than the first surface roughness.
